(19) United States
(12) Patent Application Publication
(10) Pub. No.: US 2026/0143697 A1
(43) Pub. Date: May 21, 2026

(54) ANTIFUSE THYRISTOR BIT CELL

(71) Applicant: INTERNATIONAL BUSINESS MACHINES CORPORATION, ARMONK, NY (US)

(72) Inventors: Robert Gauthier, Williston, VT (US); Anindya Nath, Watervliet, NY (US); Jens Haetty, Halfmoon, NY (US); Masoud Zabihi, Schenectady, NY (US); Anthony I-Chih Chou, Guilderland, NY (US); Dan Moy, Bethel, CT (US)

(21) Appl. No.: 18/955,863

(22) Filed: Nov. 21, 2024

(51) Int. Cl. H10B 20/10

(52) U.S. Cl. CPC H10B 20/10

(57) ABSTRACT

An electrical antifuse bit cell structure includes a silicon controlled rectifier (SCR) having an anode, a cathode, and a blow gate. The blow gate is a Positive Field Effect Transistor (PFET) having a supply node for connection in series between a voltage supply and the anode of the SCR. The blow gate PFET in an on-state provides a permanent conductive path from the anode to the cathode.

### BACKGROUND

### Technical Field

The present disclosure generally relates to bit cells having a construction that includes fuse elements, and more particularly, to an antifuse bit cell structure.

### Description of the Related Art

Electronic fuses (e.g., eFuses and antifuses) are complementary components in operation that have increased in popularity due to a One Time Programmable (OTP) feature. For example, an eFuse opens an electrical path when blown, and an antifuse closes an electrical path when blown. In recent years, information has been stored on bit cell structures through the use of such fuses.

### SUMMARY

In an embodiment, an electrical antifuse structure includes a silicon-controlled rectifier (SCR) having an anode, a cathode, and a blow gate. The blow gate is constructed of a Positive Field Effect Transistor (PFET) having a supply node for connection in series between a voltage supply and the anode of the SCR. In an on-state (often referred to as “blow state”), the blow gate PFET provides a permanent conductive path from the anode to the cathode.

In an embodiment, which may be combined with the preceding embodiment, the SCR has a minimum diffusion width (RX)≤100 nm that forms the permanent conductive path from the anode to the cathode.

In an embodiment, which may be combined with one or more of the preceding embodiments, the SCR is a three-junction device made of four layers in a PNPN arrangement.

In an embodiment, which may be combined with one or more of the preceding embodiments, the four layers of the PNPN arrangement (i.e., alternate arrangement) include a P-well layer, an N layer, a P layer, and an N-well layer.

In an embodiment, which may be combined with one or more of the preceding embodiments, the blow gate has a resistance of greater than 2 megaohms in an off-state and less than 100 ohms in an on-state.

In an embodiment, which may be combined with one or more of the preceding embodiments, the electrical antifuse structure includes a sense node coupled to the anode of the SCR.

In an embodiment, which may be combined with one or more of the preceding embodiments, the electrical antifuse structure includes a first control FET coupled from a PNP emitter to a PNP base of the SCR.

In an embodiment, which may be combined with one or more of the preceding embodiments, the electrical antifuse structure further includes a second control FET coupled from a PNP base to an NPN base of the SCR.

In an embodiment, which may be combined with one or more of the preceding embodiments, the electrical antifuse structure includes at least one series leakage control diode coupled from the cathode of the SCR to ground.

In an embodiment, which may be combined with one or more of the preceding embodiments, the blow gate PFET on-state is about 1 to 1.5 volts.

In an embodiment, which may be combined with one or more of the preceding embodiments, the blow gate PFET operates in the on-state at about 0.5 mA.

In an embodiment, which may be combined with one or more of the preceding embodiments, a sense node voltage in an off-state of the SCR is scalable according to a quantity of the trigger diodes coupled to the cathode of the SCR.

In an embodiment, which may be combined with one or more of the preceding embodiments, the SCR is constructed of a PNP bipolar junction transistor (BJT) and an NPN BJT. The antifuse structure further includes a first control FET coupled from an emitter to a base of the PNP BJT.

In an embodiment, which may be combined with one or more of the preceding embodiments, the electrical antifuse bit cell structure further includes a second control FET coupled from the base of the PNP BJT to a base of NPN BJT.

In an embodiment, which may be combined with one or more of the preceding embodiments, the antifuse bit cell structure is part of a chip having a nanosheet architecture.

In an embodiment, which may be combined with one or more of the preceding embodiments, the antifuse bit cell structure is part of a chip having a FinFET architecture.

In an embodiment, which may be combined with one or more of the preceding embodiments, the antifuse bit cell structure is part of a chip having a planar architecture.

In an embodiment, which may be combined with one or more of the preceding embodiments, the antifuse bit cell structure is constructed with Vertical FET technology.

In an embodiment, a method of making an electrical antifuse bit cell structure includes providing a silicon-controlled rectifier having an anode and a cathode, and a blow gate including a Positive Field Effect Transistor (PFET). The blow gate PFET is coupled in series between a voltage supply node and the anode of the SCR. The blow gate PFET is configured to provide in an initial on-state current of about 0.5 mA to form a permanent conductive path from the anode to the cathode of the SCR.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition to or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 is an illustration of an SCR antifuse bit cell structure according to an illustrative embodiment.

FIG. 2 is an illustration of an SCR antifuse bit cell structure including a trigger additional diode, according to an illustrative embodiment.

FIG. 3 is an illustration of an SCR antifuse bit cell structure including a first control FET according to an illustrative embodiment.

FIG. 4 is an illustration of an SCR antifuse bit cell structure including a first control FET and a second control FET according to an illustrative embodiment.

FIG. 5 illustrates an SCR antifuse bit cell structure in which an NWell, PWell, P+, and N+ contact areas are shown, according to an illustrative embodiment.

FIG. 6 illustrates an SCR antifuse bit cell structure in cross-section constructed from nanosheet technology, according to an illustrative embodiment.

FIG. 7 illustrates an SCR antifuse bit cell structure in cross-section showing a post-blow filamentation path, according to an illustrative embodiment.

FIG. 8 shows an SCR antifuse bit cell structure after it is blown to create a filamentation path post program, according to an illustrative embodiment.

FIG. 9 is a flowchart illustrating a method of making an electrical antifuse bit cell structure according to an illustrative embodiment.

### DETAILED DESCRIPTION

In the following detailed description, numerous specific details are set forth by way of examples to provide a thorough understanding of the relevant teachings. However, it should be understood that the present teachings may be practiced without such details. In other instances, well-known methods, procedures, components, and/or circuitry have been described at a relatively high level, without detail, to avoid unnecessarily obscuring aspects of the present teachings.

As used herein the term “minimum diffusion width (RX)” in an antifuse refers to a smallest width of a diffusion region in a semiconductor device. The diffusion region is used to form a conductive path when an antifuse is programmed.

As used herein, the term “silicon-controlled rectifier” (SCR) refers to a three-junction device having four silicon layers alternately-arranged on a substrate (e.g. pnpn) and a gate. A SCR is also known in the art as a thyristor.

### Overview

Antifuses may be used for a permanent programming of integrated circuits, such as a programmable read-only memory (PROM). For example, a memory cell may include one or both of an eFuse and an antifuse, and may be programmed one time (i.e., one time programming (OTP)) by triggering one of the eFuse/antifuse. Such OTP is permanent and may be used to store identifying information about an integrated circuit. Accordingly the eFuse and antifuse provide a way to store information that isn't expected to change. For instance, the lot number and the date of manufacture for a particular chip, information to trim a device with a certain resistor value to reduce the voltage to a desired range, and information about the speed of a chip are just a few of the various types of information that may be written into the eFuse or antifuse.

Whereas conventional antifuses have a blow gate voltage of around 3 to 4 volts to cause a meltdown that forms the conduction path, the SCR antifuse bit cell structure has a blow gate voltage that is much lower, from about 2 volts or less. In some embodiments of the present disclosure, an SCR antifuse bit cell structure has a blow gate voltage between 1 to 1.5 volts, significantly less than the 3 to 4 volts used for conventional antifuses. In turn, the lower blow gate voltage results in a reduction of the anitfuse blow current than previously known. For example, an approximately 10x reduction in the antifuse blow current has been achieved in the present antifuse structure than in previously known efuse structures. Whereas efuses typically have blow current of 10 mA or more, the antifuse according to the present disclosure will blow at 1ma or lower. In general, anti-fuses always blow at a lower current than efuses. However, the problem with known anti-fuses was that it can take 3-4V or more to blow the antifuse (which is too high), and this SCR antifuse overcomes the high blow voltage issue and still has a low programming current.

The SCR antifuse bit cell structure may be applied to any structure where a diffusion width (RX) is 0.1 um or smaller. The antifuse bit cell structure may be constructed using nanosheet technology, FinFET technology, planar technology, Vertical FET technology, etc., just to name some possible non-limiting constructions.

### Example Embodiment(s)

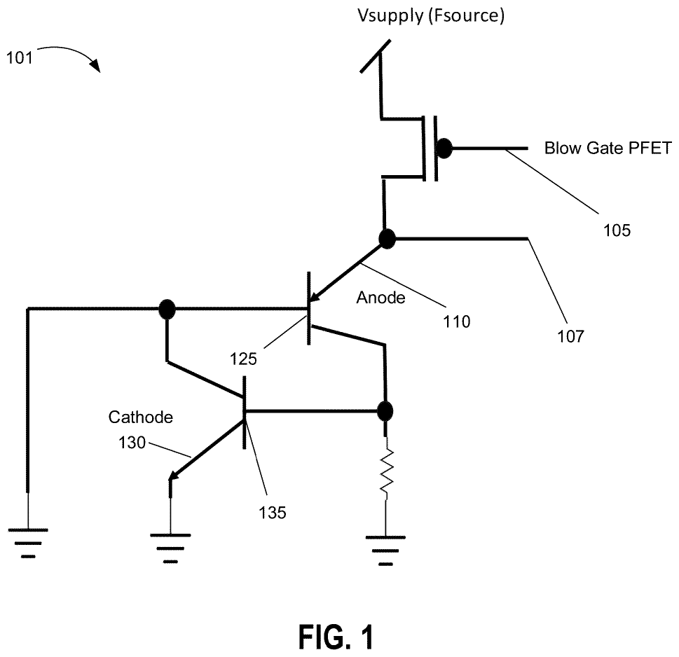

FIG. 1 is an illustration of an SCR antifuse structure according to an illustrative embodiment. It is to be understood that various configurations of the SCR antifuse structure of the present disclosure may be constructed.

The SCR antifuse bit cell structure 101 is a four-layer structure that includes an anode 110, a cathode 130, and a blow gate PFET 105. In this embodiment, the four-layer structure is shown as two transistors, a PNP 125 and an NPN 135, which are considered in the SCR to be an anode and a cathode. A resistor 137 intrinsic or extrinsic to the SCR can be used to adjust the programming current. A sense node 107 operates at a low voltage (typically between 0.5 volts and 1 volt), during this sensing the blow gate PFET 105 would remain off. Through the use of triggering diodes, the sense node voltage may be set between, for example, 0.5 volts to 1 volt. When activated, the blow PFET gate 150 will cause the formation of a permanent conduction path from anode 110 to cathode 130 which is a one-time programmable (OTP) feature to store information in the bit cell. The arrangement of arrays of the SCR antifuse bit cell structure 101 may be provided. For example, there may be a construction of bit cell structures on a nanosheet.

Initially, the SCR antifuse bit cell structure 101 is in the unprogrammed state. Until there is sufficient current, the bit cell structure is operating like a diode string. When the supply voltage initially is turned on, there is current flowing, the diode string turns on, and, with sufficient current, the SCR antifuse bit cell structure 101 turns on. When the SCR turns on, there is a melting in a region between the anode 110 and the cathode 130 to create a filament (e.g., a conduction path).

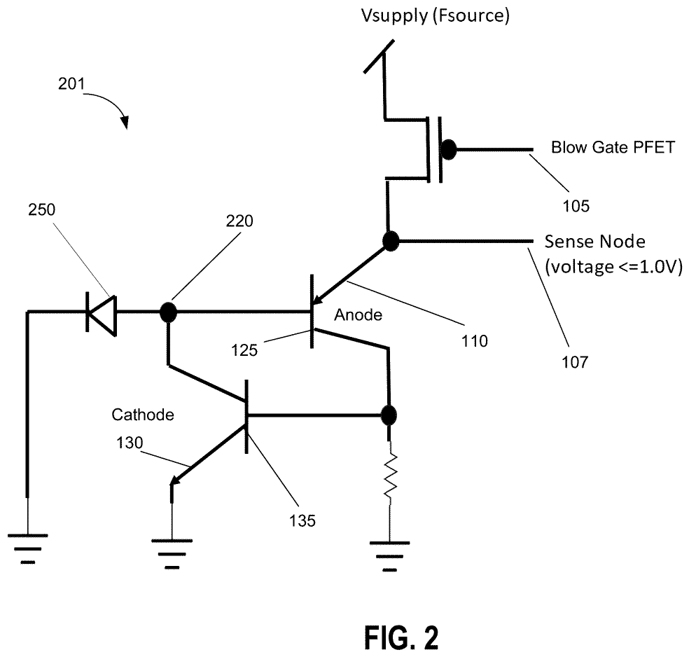

FIG. 2 is an illustration of an SCR antifuse bit cell structure 201 including a trigger additional diode, according to an illustrative embodiment. FIG. 2 includes the addition of at least one diode 250 that may be coupled to the cathode 130 via the node 220. The diode 250 may be referred to as a “trigger diode”. Multiple diodes may be coupled to the bit cell structure 201. When the voltage increases and the current is flowing, the diode string turns on, and, the PNP turns on. With sufficient current, the SCR turns on. The trigger diode 250 causes the SCR antifuse bit cell structure 201 to initially have a higher impedance than if there was no trigger diode such as the structure shown in FIG. 1. The trigger diode may be desirable in a case where a sense voltage of 1 v is too high for the SCR. By trying to use the sense voltage to check the device, it might be sufficiently high to inadvertently activate the SCR and create a conduction path that would make the bit cell unsuitable for storing a bit because the programming is done at the same time the conduction path is created. By adding one or more trigger diodes, the sense voltage can be reduced.

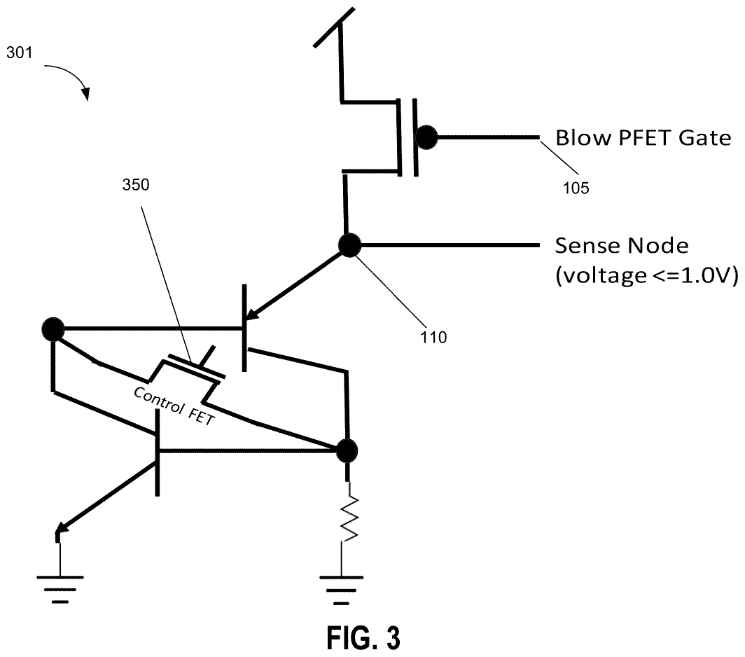

FIG. 3 is an illustration of an SCR antifuse bit cell structure including a first control FET 350 according to an illustrative embodiment. The bit cell stricture 301 is similar to the structure shown in FIG. 1, with the addition of a first control FET 350 coupled base from an emitter to a base of the PNP transistor 125. The first control FET 350 may be used instead of diodes to provide/block a sensing voltage from the NPN, when the blow gate PFET is off, but will permit programming when the blow gate PFET is turned on. The blow gate PFET may have a resistance of ≥2K ohm in an off-state (e.g., a diode forward bias resistance) and ≤100 ohms in an on-state (e.g., an SCR short to ground). The additional use of trigger diodes such as shown in FIG. 2 will increase the programming voltage of the SCR.

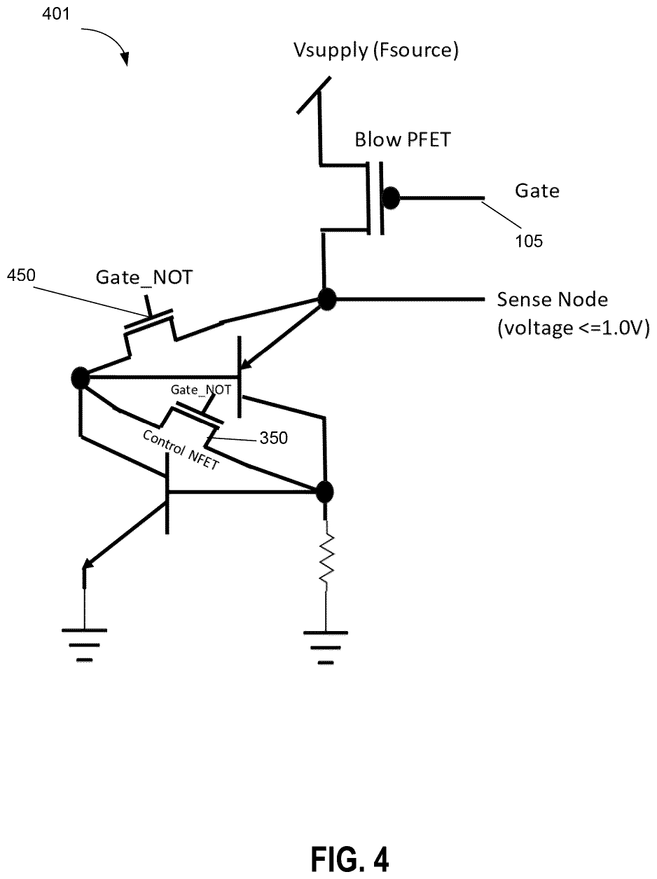

FIG. 4 is an illustration of an SCR antifuse bit cell structure 401 including a first control FET 350 and a second control FET 450 according to an illustrative embodiment. The bit cell structure 401 differs from the structure shown in FIG. 3 by the addition of the second control FET 450. The combination of the two control FETs 350,450 provides a way to control the leakage current of the bit cell structure prior to programming.

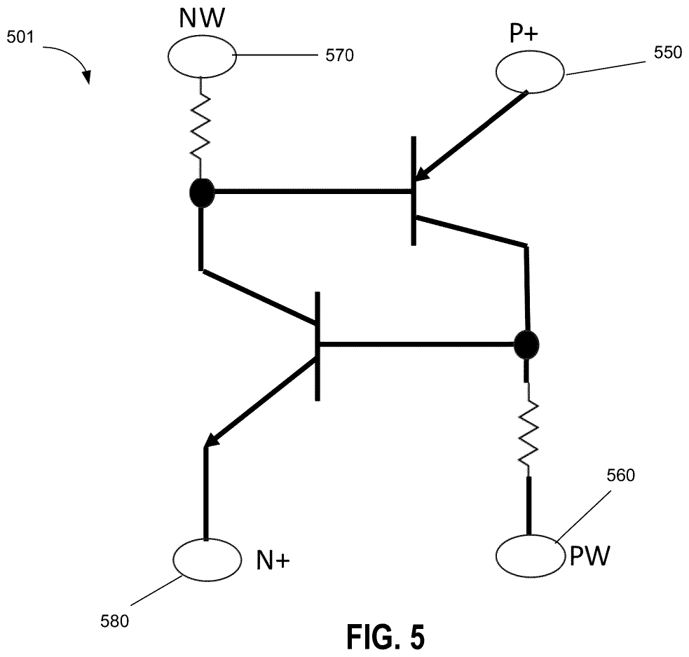

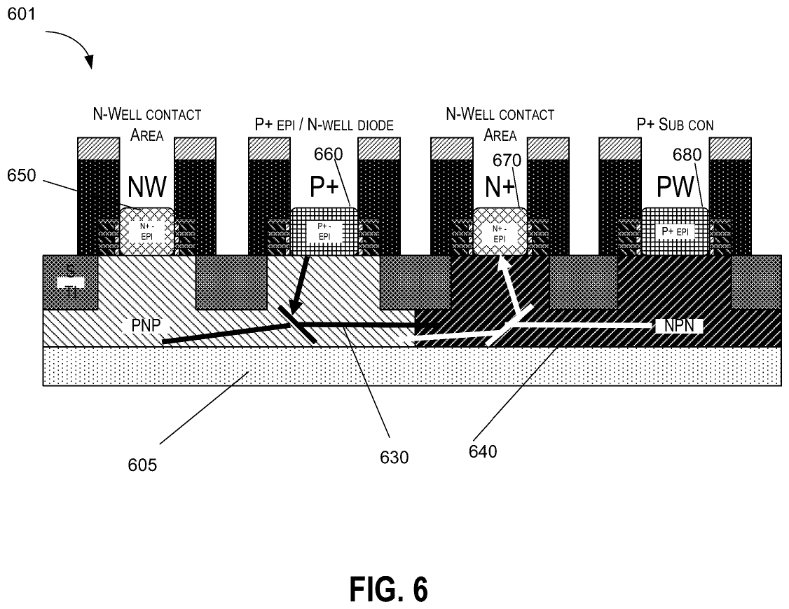

FIG. 5 illustrates an SCR antifuse bit cell structure in which an NWell, PWell, P+, and N+ contact areas are shown, according to an illustrative embodiment. Here there is shown the P+ 550, P-well 560, N-Well 570, and N+ 580 sections that are shown in FIG. 6. There is a conduction path formed by a melting of the P+to N+, creating a very narrow diffusion width (RX) of about 0.1 um or smaller. The diffusion width (RX) may be half of the 0.1 um size.

FIG. 6 illustrates an SCR antifuse bit cell structure 601 in cross-section constructed from nanosheet technology, according to an illustrative embodiment. There is a substrate 605 (typically a p-type substrate) and the transistor arrangement of the SCR 630, 640 are shown, with an NPN 630 and a PNP 640. FIG. 6 shows the structure prior to programming.

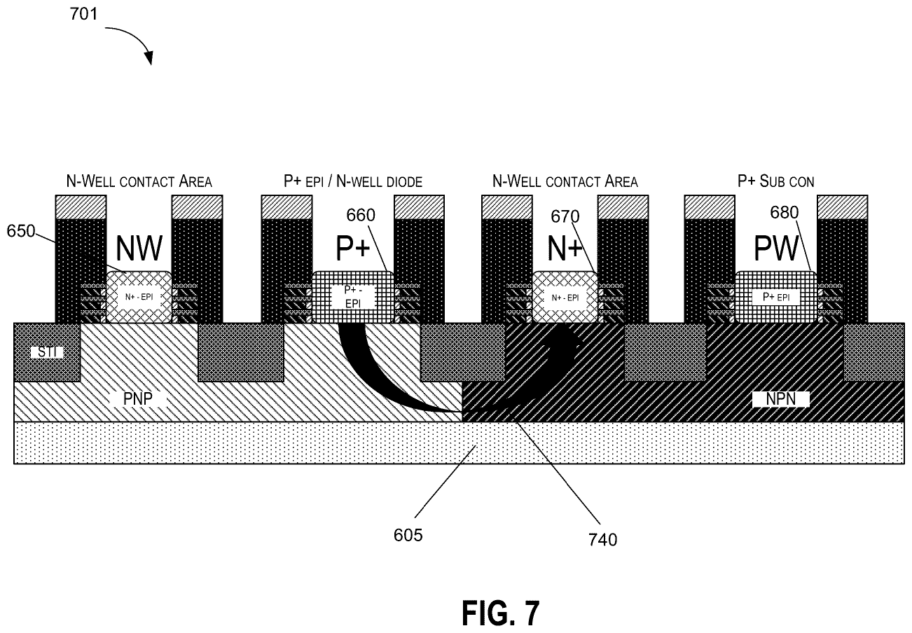

FIG. 7 illustrates an SCR antifuse bit cell structure 701 in cross-section showing a post-blow filamentation path (low resistance from anode to cathode), according to an illustrative embodiment. For the sake of brevity, conventional techniques related to semiconductor devices and integrated circuit (IC) fabrication are not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

The fabrication of the structures described herein can comprise multi-step sequences of, for example, photolithographic and/or chemical processing steps that facilitate the gradual creation of electronic-based systems, devices, components, and/or circuits in a semiconducting and/or a superconducting device (e.g., an integrated circuit). For instance, structure 601 can be fabricated on one or more substrates (e.g., a silicon (Si) substrates, and/or another substrate) by employing techniques including, but not limited to: photolithography, microlithography, nanolithography, nanoimprint lithography, photomasking techniques, patterning techniques, photoresist techniques (e.g., positive-tone photoresist, negative-tone photoresist, hybrid-tone photoresist, and/or another photoresist technique), etching techniques (e.g., reactive ion etching (RIE), dry etching, wet etching, ion beam etching, plasma etching, laser ablation, and/or another etching technique), evaporation techniques, sputtering techniques, plasma ashing techniques, thermal treatments (e.g., rapid thermal anneal, furnace anneals, thermal oxidation, and/or another thermal treatment), chemical vapor deposition (CVD), atomic layer deposition (ALD), physical vapor deposition (PVD), molecular beam epitaxy (MBE), electrochemical deposition (ECD), chemical-mechanical planarization (CMP), backgrinding techniques, and/or another technique for fabricating an integrated circuit.

Upon a voltage applied to the N-well contact area 650, an amount of current ranging from about 0.5 mA to 1 mA creates a conduction path 740 (see FIG. 7) between P+ 660 and N+ 670. This conduction path 740 is created by diffusion of the silicon from the two transistors 630, 640 shown in FIG. 6.

FIG. 7 shows the structure of the bit cell post programming. It can be seen that the transistors 630 and 640 shown in FIG. 6 are now replaced with an arrow which represents a conductive path 740 from the anode P+ 660 to the cathode N+ 670 after meltdown. In other words, once the blow gate PFET is activated, there is a conductive path 740 created which can be used for a One Time Programmable (OTP) storage in the bit cell.

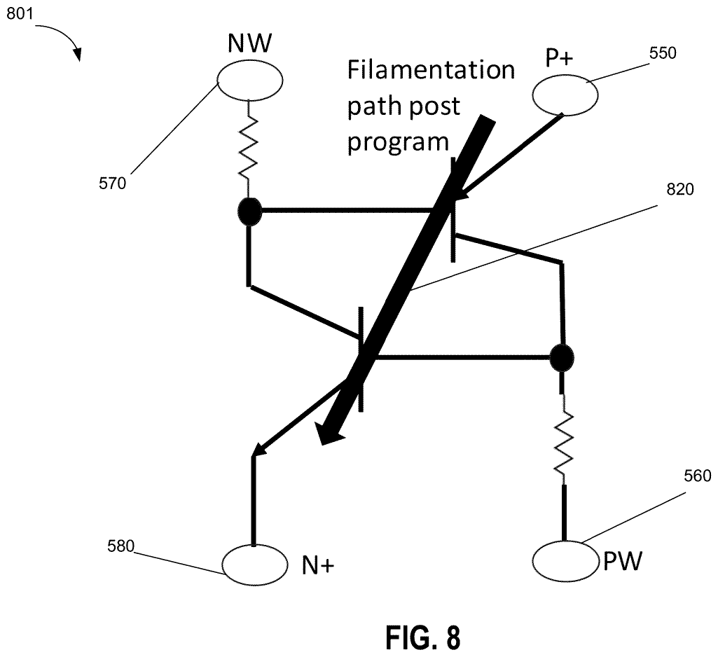

FIG. 8 shows an SCR antifuse bit cell structure 801 after being blown to create a filamentation path post-programming, according to an illustrative embodiment. FIG. 8 is essentially the structure of FIG. 5 including the newly created conduction path 820 from the anode P+ to the cathode N+.

Accordingly, a relatively smaller amount of current than known heretofore is applied and after the SCR turns on the conduction path is melted because of the narrow diffusion width.

Example Process

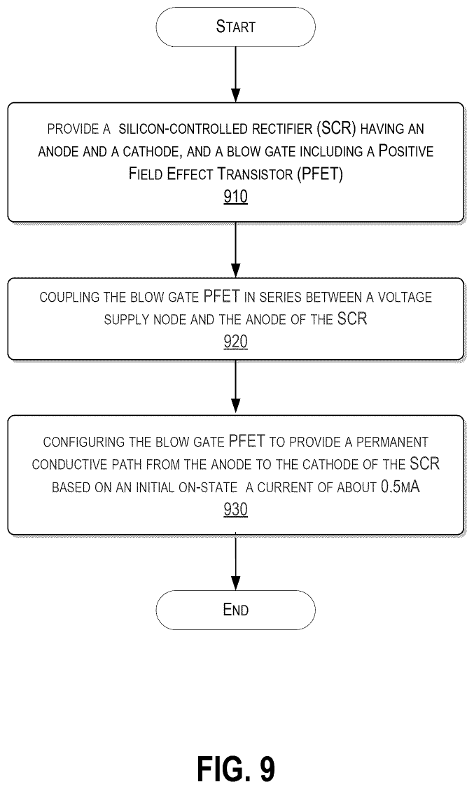

With the foregoing overview of the example architecture, it may be helpful to now consider a high-level view of an example process. To that end, FIG. 9 provides a flowchart illustrating the operations to construct an electrical antifuse bit cell structure consistent with an illustrative embodiment, such as shown in FIGS. 1 and 2.

FIG. 9 is shown as a collection of blocks, in a logical order, which can represent a sequence of operations that can be implemented in a combination thereof. A silicon-controlled rectifier (SCR) is provided (operation 910). The SCR has an anode and a cathode, and a blow gate that is a Positive Field Effect Transistor (PFET). For example, FIGS. 1 and 2 show a blow gate PFET 105 and the SCR having an anode and a cathode.

The blow gate PFET is coupled in series between a voltage supply node and the anode of the SCR (operation 920). It is shown in FIGS. 1 and 2 that the blow gate PFET 105 is coupled between the supply source node and the anode 110 of the SCR.

The blow gate PFET is configured to provide a permanent conductive path from the anode to the cathode of the SCR based on an initial on-state current of about 0.5 mA (operation 930). By constructing the SCR antifuse to have a diffusion width of less than about 100 um between the layers forming the three junctions, a low current of about 0.5 mA can be used to cause the antifuse to meltdown and form a permanent conduction path from anode to cathode that may be used for one time programming. FIG. 8 shows the filamentation conduction path 820 after the initial meltdown current has been applied.

The method ends in its most basic form, as illustrated by the flowchart in FIG. 9. However additional construction operations are possible as taught by the description of the embodiments of the present disclosure.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, operations, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

The diagrams in the figures herein illustrate the architecture, functionality, and operation of possible implementations according to various embodiments of the present disclosure.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any such actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. An electrical antifuse bit cell structure, comprising:
a silicon-controlled rectifier (SCR) having an anode, a cathode, and a blow gate, wherein:
the blow gate comprises a Positive Field Effect Transistor (PFET) having a supply node for connection in series between a voltage supply and the anode of the SCR; and
the blow gate PFET in an on-state provides a permanent conductive path from the anode to the cathode.

2. The electrical antifuse bit cell structure according to claim 1, wherein the SCR has a diffusion width (RX)≤50 nm that forms the permanent conductive path from the anode to the cathode.

3. The electrical antifuse bit cell structure according to claim 1, wherein the SCR has a diffusion width (RX)≤100 nm that forms the permanent conductive path from the anode to the cathode.

4. The electrical antifuse bit cell structure according to claim 3, wherein the SCR is a three-junction device comprising four alternately-arranged silicon comprising a P-well layer, an N layer, a P layer, and an N-well layer on a substrate.

5. The electrical antifuse bit cell structure according to claim 1, wherein the blow gate PFET has a resistance ≥2 megaohms in an off-state and ≤100 ohms in an on-state.

6. The electrical antifuse bit cell structure according to claim 1, further comprising a sense node coupled to the anode of the SCR.

7. The electrical antifuse bit cell structure according to claim 6, wherein a sense node voltage in an off-state of the SCR is less than 1 volt.

8. The electrical antifuse bit cell structure according to claim 6, wherein a sense node voltage in an off-state of the SCR is less than 0.5 volts.

9. The electrical antifuse bit cell structure according to claim 6, further comprising one or more trigger diodes coupled to the cathode of the SCR and ground.

10. The electrical antifuse bit cell structure according to claim 9, wherein a sense node voltage in an off-state of the SCR is scalable according to a quantity of the trigger diodes coupled to the cathode of the SCR.

11. The electrical antifuse bit cell structure according to claim 1, wherein the SCR is constructed of a PNP bipolar junction transistor (BJT) and an NPN BJT, and the electrical antifuse bit cell structure further comprising a first control FET coupled from an emitter to a base of the PNP BJT.

12. The electrical antifuse bit cell structure according to claim 11, further comprising a second control FET coupled from the base of the PNP BJT to a base of NPN BJT.

13. The electrical antifuse bit cell structure according to claim 1, further comprising at least one series leakage control diode coupled from the cathode of the SCR to ground.

14. The electrical antifuse bit cell structure according to claim 1, wherein the blow gate PFET has an on-state ranging from about 1 to 1.5 volts.

15. The electrical antifuse bit cell structure according to claim 1, wherein the blow gate PFET has a programming current of about 0.5 mA or higher.

16. The electrical antifuse bit cell structure according to claim 1, wherein the electrical antifuse bit cell structure is part of a chip having a nanosheet architecture.

17. The electrical antifuse bit cell structure according to claim 1, wherein the electrical antifuse bit cell structure is part of a chip having a FinFET architecture.

18. The electrical antifuse bit cell structure according to claim 1, wherein the electrical antifuse bit cell structure is part of a chip having a planar architecture.

19. The electrical antifuse bit cell structure according to claim 1, wherein the electrical antifuse bit cell structure is part of a chip constructed with a Vertical FET architecture.

20. A method of making an electrical antifuse bit cell structure, the method comprising:
providing a silicon-controlled rectifier (SCR) having an anode and a cathode, and a blow gate comprising a Positive Field Effect Transistor (PFET);
coupling the blow gate PFET in series between a voltage supply node and the anode of the SCR; and
configuring the blow gate PFET to provide a permanent conductive path from the anode to the cathode of the SCR based on an initial on-state current of about 0.5 mA.
